(19) United States
(12) Patent Application Publication
(10) Pub. No.: US 2026/0352180 A1
(43) Pub. Date: Nov. 5, 2026

(54) LOW-LOSS ACOUSTIC WAVE STRUCTURES, DEVICES AND METHODS

(71) Applicant: Arizona Board of Regents on Behalf of the University of Arizona, Tucson, AZ (US)

(72) Inventors: Pierre Deymier, Tucson, AZ (US); Keith Runge, Gainesville, FL (US)

(21) Appl. No.: 19/487,702

(22) PCT Filed: May 30, 2024
(86) PCT No.: PCT/US2024/031708

§ 371 Date: Nov. 25, 2025

Related U.S. Application Data
(60) Provisional application No. 63/505,565, filed on Jun. 1, 2023.

(51) Int. Cl. H03H 9/02

(52) U.S. Cl. CPC H03H 9/02866

(57) ABSTRACT

Acoustic wave devices, structures and methods are described that reduce or eliminate return losses due to reflections caused by impedance mismatch. The described features and benefits are achieved without increasing the footprint of the device and improve the power budget of the acoustic wave device. An example acoustic wave device includes an input transducer, an acoustic material, and an output transducer. The acoustic material includes a number of unit cells, each having a first layer and a second layer with differing materials. Impedance values associated with the input layer, the detection layer, and/or one or both of the first layer or the second layer of the unit cells are selected to allow the input acoustic wave to propagate within the acoustic material in a first direction with substantially no backscattered acoustic waves in the opposite direction.

### CROSS-REFERENCE TO RELATED APPLICATION(S)

This application claims priority to the provisional application with Ser. No. 63/505,565 titled “LOW-LOSS ACOUSTIC WAVE STRUCTURES, DEVICES AND METHODS,” filed Jun. 1, 2023. The entire contents of the above noted provisional application are incorporated by reference as part of the disclosure of this document.

### TECHNICAL FIELD

This description in this patent document relates acoustic wave devices, methods and structures.

### BACKGROUND

Acoustic wave (AW) devices, such as bulk acoustic wave (BAW) devices, surface acoustic wave (SAW) devices, and Love wave (LW) devices find many applications including, but not limited to, radio frequency (RF) telecommunication, and sensing, and can be found in a variety of devices, such as medical device and consumer devices. Some example applications and use cases include utilization of SAW filters in cellular phones, wireless networks, consumer electronics (such as televisions, radios, and MP3 players), GPS receivers, and radar systems to filter out unwanted frequencies and improve signal detection. The use of acoustic components in sensors can facilitate sensing of physical quantities, such as pressure, temperature, altitude and humidity that can be used for environmental sensing, seismology, industrial automation, unmanned aerial vehicles, autonomous vehicles and many others. It is beneficial to improve the operation and design of acoustic wave devices.

### SUMMARY

The disclosed embodiments relate to acoustical wave structures, devices and methodology that, among other features and benefits, aim to reduce the power loss in acoustical devices. This objective is achieved by reducing or eliminating return losses that are due to one or more reflections due to impedance mismatch, and is achieved without increasing the footprint of the device.

One example acoustic wave device includes an input transducer configured to produce an input acoustic wave, an acoustic material coupled to the input transducer to receive the acoustic wave, and an output transducer coupled to the acoustic material and configured to receive a transmitted acoustic wave from the acoustic material and to produce electrical signals in response to receiving the transmitted acoustic wave. The acoustic material is structured to include a plurality of unit cells, where each unit cell includes a first layer and a second layer, the first layer and the second layer have differing materials, the input transducer is configured to couple the input acoustic wave to the acoustic material through an input layer, the output transducer is configured to receive the transmitted acoustic wave through a detection layer, and impedance values associated with (a) one or both of the input layer or the detection layer, and (b) one or both of the first or the second layers of the unit cells, are selected to allow the input acoustic wave to propagate within the acoustic material in a first direction with substantially no backscattered acoustic waves in a second direction opposite to the first direction.

### BRIEF DESCRIPTION OF THE DRAWINGS

FIG. 1 illustrates a block diagram of a typical acoustic wave device that includes an input transducer that impart acoustic wave vibrations onto a material.

FIG. 2 illustrates schematic representations of an infinite superlattice structure in panel (a), and a finite superlattice structure in panel (b) that can be implemented as part of an acoustic device in accordance with example embodiments.

FIG. 3 illustrates the band structure of an infinite superlattice and the real and imaginary parts of the amplitudes of forward and backward propagating waves.

FIG. 4 illustrates transmission coefficient plots for input and detection layers of an acoustic wave device in accordance with an example embodiment.

FIG. 5 illustrates a set of operations that can be carried out to produce an acoustical structure with enhanced transmission characteristics in accordance with an example embodiment.

### DETAILED DESCRIPTION

In typical configurations, acoustic devices include an input transducer for transduction of an acoustic wave that produce, for example a Love wave in a thin film deposited on a piezoelectric substrate, or a Rayleigh wave on the surface of a piezoelectric material. Rayleigh wave is the elastic energy propagation along a free surface of a solid substrate of infinite depth. An acoustic wave device also includes an output transducer to detect the received acoustic wave. Transduction and detection typically use interdigital transducers (IDTs), with the primary function to convert electric signals to surface acoustic waves by generating mechanical forces via piezoelectric effect, and vice versa.

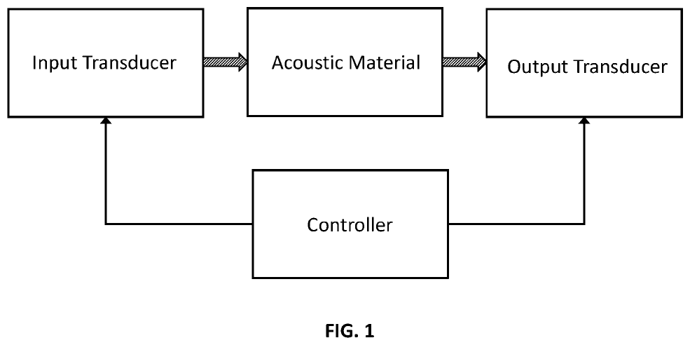

FIG. 1 illustrates a block diagram of a typical acoustic wave device that includes an input transducer that is coupled to an acoustic material and impart acoustic wave vibrations onto the material. A controller (or a processor) can be used to control the operation of the input transducer by, for example, controlling the amplitude and/or phase of the acoustic wave. An output transducer (sometimes called a detection transducer) detects the acoustic waves and produces electrical signals associated with the detected waves. The same controller (or a different controller or processor) can receive the electrical signals and produce the corresponding detection information. In some implementations at least part of the functionality of the controller(s) may be incorporated into the transducers. The acoustic material may be designed to provide a particular functionality, such as to filter a specific frequency or range of frequencies. One of the benefits of acoustic technology is that, for the same radio frequency, the wavelength of acoustic waves is roughly a hundred thousand times smaller than a corresponding electromagnetic wave at that frequency. Additionally, acoustic wave devices for RF and sensing applications exhibit very high-quality factors. Accordingly, acoustical devices may be implemented with much smaller footprints and/or to provide additional functionalities per given (fixed) volume or area.

One of the challenges with acoustic wave devices is that their performance is strongly affected by loss. Insertion loss is an important performance metric of acoustic wave devices that is defined as the ratio of power transmitted to the output transducers and the incident power. In part, insertion loss results from reflections that cause return loss, and in part by parasitic absorption. Return loss measures the amount of reflected signal caused by the mismatch between the impedance of the transduction regions of the device and that of the region between the transducers. Return loss adversely affects the performance of acoustic RF devices and constitutes a major technical barrier in today's AW device technology. The reflections can also create additional signals that could propagate back and forth via multiple reflections and produce additional unwanted noise.

Today's acceptable power loss in acoustical devices is about 6 dB for return loss. One of the objectives of the disclosed embodiments is to reduce the power loss in acoustical devices, and in particular return losses that are due to one or more reflections due to impedance mismatch without increasing the footprint of the device. In terms of practical implications, reducing the return loss improves the power budget, which can be especially important for battery-powered electronic devices by (a) allowing additional functions or operations to be carried out by the electronic device with the same power budget, (b) reduce the footprint and weight associated with the battery, and/or (c) improve the useful lifetime of the battery since, due to lower power consumption, the number of charging cycles are reduced.

The emerging field of topological acoustics provides fertile ground to address some of the technological challenges faced by current AW device technologies. In particular, the phenomenon of one-way propagation (i.e., immunity to backscattering or echo) of topologically protected acoustic waves may enable the design of AW devices with reduced return loss. That is, the media is designed in such a way to allow the wave to propagate only in one direction within the media.

Topological protection, potentially leading to immunity against scattering of an incident wave by a discontinuity in impedance, requires a counter-propagating wave that: (1) is orthogonal to the incident wave; or (2) has no amplitude (i.e., does not exist at all). The first case corresponds to topological edge/interface waves that conserve time-reversal symmetry. Edge and interface states live at the surface of acoustic topological insulators or at interfaces between topological insulators with different topological characteristics. The second case corresponds to bulk waves that break time-reversal symmetry via, for instance, spatio-temporal modulation of the elastic properties of the wave-supporting medium. Time-reversal-symmetry-preserved topological edge/interface waves are not robust against all types of scatterers. Only scatterers that cannot mix orthogonal waves will be invisible to the incident wave, and can be most effective only in particular regions at the interface or edge locations. Edge/interface waves therefore may not offer a robust solution to reducing return loss in AW devices. Furthermore, integration of expansive topological insulating phononic structures that support edge/interface states into AW devices may challenge device miniaturization. In the second case, the waves that break time-reversal-symmetry are more robust against backscattering. However, the physical realization of spatio-temporal modulation in, for instance, a piezoelectric medium may be impractical, or at best prohibitively costly, for mass produced AW devices. For example, spatio-temporal modulation requires using additional power which is in contrast to the objective of reducing power consumption.

The disclosed embodiments address the shortcomings of the prior systems by using topologically protected elastic waves which do not require time modulations and offer a path toward practical design of AW devices with no, or low, return loss. In the 1980s and 1990s the focus of studies of elastic waves in superlattices was on their frequency gaps (i.e., Bragg gaps) or on localized modes at free surfaces or at interfaces in semi-infinite and finite superlattices. Following more recent work on the topological properties of electromagnetic superlattices, we discovered topologically protected elastic waves which propagate in infinite static superlattices with nonzero amplitude in the forward direction but zero amplitude in the backward direction.

As described herein, the disclosed technology can be implemented in various embodiments to produce superlattices that include a finite number of layers to eliminate or reduce reflections at a particular range of frequencies. As such, by inserting an appropriately designed superlattice between the IDTs in an acoustic RF device, return loss can be reduced or eliminated. The topologically protected elastic waves produced in this matter do not possess the wider bandwidth that other topologically protected waves may possess; however, their relatively narrow operational range of frequency can be specifically tailored based on a plurality of parameters, such as the number of layers, the material properties of the layers, and the thickness of the layers, which allow the structured acoustic material to be advantageously integrated with the current narrow band AW devices. In some examples, the pass band can be 1% or 2% of the acoustic spectra.

We note that the fabrication of superlattices in the form of Bragg gratings can be implemented via current RF device manufacturing; however, these gratings are used for their reflection capabilities due to their band gaps. In contrast, one of the features of the disclosed embodiments relates to a superlattice topological acoustic-based solution to reduce insertion/return loss in AW devices, which provides an attractive and disruptive innovation for industrial applications.

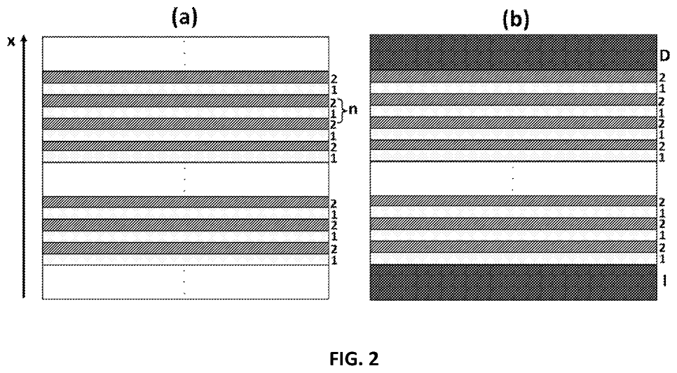

FIG. 2 illustrates schematic representations of an infinite superlattice structure in panel (a), and a finite superlattice structure in panel (b) that can be implemented as part of an acoustic device. Each structure includes alternating layers with differing materials identified by “1” and “2.” In FIG. 1, “x” represents the direction of acoustic wave propagation (perpendicular to the layers). In panel (b), the prototypical structure includes an input layer “I,” from which incident waves are emitted and a detection layer “D”,” where transmitted waves are detected. The input and detection layers can be part of the input and detection transducers.

The following explanation facilitates the understanding of the concepts. In this analysis, we focus on transverse waves with a displacement in the plane of the superlative layers. The displacement field in the infinite superlattice composed of two types of materials 1 and 2 takes the form of Bloch waves, namely:

u(x)=e^{iqx}u(q,x) (1)

In Eq. (1), the wave number is

$$q ∈ [ \frac{- π}{L} , \frac{π}{L} ] .$$

The thicknesses of the alternating layers are d₁ and d₂, respectively. The period of one unit cell of the superlattice is L=d₁+d₂. The periodic functions in the layers 1 and 2 in the nth unit cell are given by:

u₁(q,x)=e^{iqnL}(A₊e^{ik}^{₁}^{(x-nL)}+A₋e^{-ik}^{₁}^{(x-nL)}) (2a)

u₂(q,x)=e^{iqnL}(B₊e^{ik}^{₂}^{(x-nl-d}^{₁}⁾+B₋e^{-ik}^{₂}^{(x-nL-d}^{₂}⁾) (2b)
with

$${k}_{1} = \frac{ω}{{c}_{1}} and {k}_{2} = \frac{ω}{{c}_{2}} .$$

A_{±} and B_{±} are the amplitude of the forward and backward propagating waves in media 1 and 2, respectively. The density and transverse speed of sound in the two types of materials are ρ₁, ρ₂ and c₁, c₂. Using continuity conditions of the displacement and of the stress at the interfaces between layers 1 and 2 and using the transfer matrix method we found the dispersion relation:

$$cos qL = cos {k}_{1} {d}_{1} cos {k}_{2} {d}_{2} - \frac{1}{2} ( F + \frac{1}{F} ) sin {k}_{1} {d}_{1} sin {k}_{2} {d}_{2} \qquad ( 3 )$$

and the amplitudes for layer 1

$${A}_{+} = \frac{1}{2} ( F - \frac{1}{l} 7 ) sin {k}_{1} {d}_{1} sin {k}_{2} {d}_{2} + \frac{i}{2} ( F - \frac{1}{F} ) cos {k}_{1} {d}_{1} sin {k}_{2} {d}_{2} \qquad ( 4 a )$$

$${A}_{-} = i [ sin {k}_{1} {d}_{1} cos {k}_{2} {d}_{2} + \frac{1}{2} ( F + \frac{1}{F} ) cos {k}_{1} {d}_{1} sin {k}_{2} {d}_{2} - sin qL ] \qquad ( 4 b )$$

and in layer 2. In layer 2 the amplitude A₋ is purely imaginary. In layer 1 the amplitude A₊ is complex.

$$( \begin{matrix}{B}_{+} \\ {B}_{-}\end{matrix} ) = \frac{1}{2} ( \begin{matrix}( 1 + F ) {α}_{1} & ( 1 - F ) {β}_{1} \\ ( 1 - F ) {α}_{1} & ( 1 + F ) {β}_{1}\end{matrix} ) ( \begin{matrix}{A}_{+} \\ {A}_{-}\end{matrix} ) \qquad ( 5 )$$

where

$${α}_{i} = {e}^{i {k}_{i} {d}_{i}} = \frac{1}{{β}_{i}} .$$

In Eqs. (4a,b) and Eq. (5),

$$F = \frac{{k}_{1} {ρ}_{1} {c}_{1}^{2}}{{k}_{2} {ρ}_{2} {c}_{2}^{2}} .$$

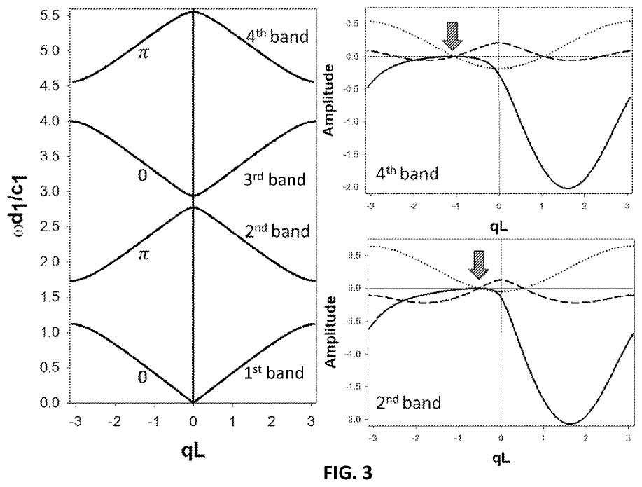

FIG. 3 illustrates the band structure of the infinite superlattice and the real and imaginary parts of the amplitudes A₊ and A₋. In particular, the left panel illustrates band structure of an infinite super lattice with the physical parameters

$$\frac{{d}_{2}}{{c}_{2}} = 1.2 \frac{{d}_{1}}{{c}_{1}} and F = 2.$$

The horizontal axis represents the wave number, and the vertical axis represents frequency. The dark lines represent passing bands and between them are band gaps that result in zero transmission. The geometric phase (Berry or Zak phase) accumulated by the elastic wave as one follows a closed path in qL space is indicated on the band structure. If a band contains the frequency point, ω₀, such that

$$sin {k}_{2}^{0} {d}_{2} = sin \frac{{ω}_{0}}{{c}_{2}} {d}_{2} = 0 ,$$

then the corresponding Berry phase (i.e., Zak phase or geometric phase over closed Brillouin zone) is equal to π. As illustrated on the left side of FIG. 3, bands 2 and 4 have a non-conventional topology with a geometric phase of π. The first and third bands correspond to conventional waves with 0 geometric phase. The panels on the right side of FIG. 3 illustrate real part (dotted line) and imaginary part (dashed line) of A₊ and imaginary part (solid line) of A₋ for transverse wave in the second band (bottom) and fourth band (top). The thick arrows mark the locations where all amplitudes are zero. In short, at locations where all amplitudes are zero-valued, there is no amplitude back-propagating in the superlattice. This condition is satisfied at different qL locations in the second band and in the fourth band, respectively.

As noted above, the second and fourth bands are topologically unconventional. At ω₀(q₀), the dispersion relation becomes cos q₀L=cos (k₁d₁+k₂d₂), A₊=0 and A₋=i[sin(k₁d₁+k₂d₂)−sin q₀L]. Since k₁d₁+k₂d₂>0, the sign of q₀ determines whether A₋ vanishes or not. In the case of FIG. 3, all the amplitudes of the waves for the second band, A, and A₋ (and the associated B₊ and B₋), are zero for negative q₀L=−0.524 but not all zero for positive q₀L=0.524. The same behavior is observed for the fourth band at q₀L=±1.048. The amplitudes for waves represented by conventional bands with zero Berry phase do not become all zero over the entire Brillouin zone. This is an example of a static superlattice supporting topologically protected elastic waves whereby a forward propagating wave does not have a backward propagating counterpart. This robust topological protection against backscattering is achieved in a static superlattice that breaks inversion symmetry but more importantly does not break time reversal symmetry.

Now, with reference to the behavior of a prototypical acoustic wave device containing a finite size superlattice (see FIG. 2(b)), the superlattice is sandwiched between an input layer “I” and a detection layer “D” with impedances that may differ from those of the materials 1 and 2. The transmission coefficient of the finite superlattice can be determined based on transfer matrices. In particular, the transmission coefficient is given by:

$$T = \frac{4 \frac{{Z}_{D}}{{Z}_{I}}}{{( \frac{{Z}_{D}}{{Z}_{1}} b - \frac{{Z}_{1}}{{Z}_{I}} c )}^{2} + {( d + \frac{{Z}_{D}}{{Z}_{I}} a )}^{2}} \qquad ( 6 )$$

$$where$$

$$a = \frac{λ - μ}{2} \frac{sin N θ}{sin θ} + cos N θ$$

$$b = σ \frac{sin N θ}{sin θ}$$

$$c = ζ \frac{sin N θ}{sin θ}$$

$$d = - \frac{λ - μ}{2} \frac{sin N θ}{sin θ} + cos N θ$$

$$In the preceding equations , we have$$

$$λ = cos {k}_{1} {d}_{1} cos {k}_{2} {d}_{2} - F sin {k}_{1} {d}_{1} sin {k}_{2} {d}_{2}$$

$$μ = cos {k}_{1} {d}_{1} cos {k}_{2} {d}_{2} - \frac{1}{F} sin {k}_{1} {d}_{1} sin {k}_{2} {d}_{2}$$

$$σ = sin {k}_{1} {d}_{1} cos {k}_{2} {d}_{2} + F cos {k}_{1} {d}_{1} sin {k}_{2} {d}_{2}$$

$$ζ = - sin {k}_{1} {d}_{1} cos {k}_{2} {d}_{2} - \frac{1}{F} cos {k}_{1} {d}_{1} sin {k}_{2} {d}_{2}$$

$$cos θ = \frac{λ + μ}{2} .$$

Where, N is the number of unit cells in the superlattice. In Eq. (6), Z₁=p₁c₁, Z_{D} and Z_{I} are the impedances of the layers of type 1, detection and input layers, respectively. The latter two impedances may represent the effect of input and detection IDTs.

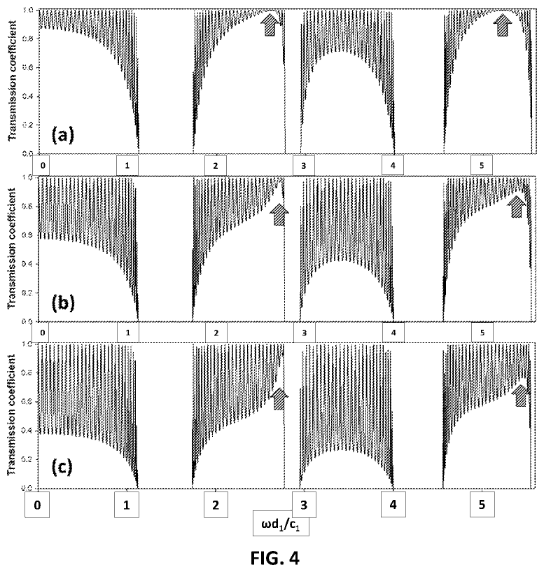

FIG. 4 illustrates plots of the transmission coefficient,

$$T ( \frac{ω}{{c}_{1}} {d}_{1} ) ,$$

for the input and detection layers of an acoustic wave device in accordance with an example embodiment. More specifically, the plots in FIG. 4 correspond to the first four bands of an example finite superlattice, having 30 (N=30) alternating layers (unit cells) with materials 1 and 2, as a function of frequency. The vertical axis represents the ratio of waves detected by a detection transducer to input acoustic wave generated by an input transducer after passing through the acoustic material. The horizontal axis in FIG. 4 represents the frequency (similar to the vertical axis in the right panel of FIG. 3). In FIG. 4's panel (a), Z_{D}=Z_{I}=Z₁, in panel (b) Z_{D}=Z_{I}=1.5Z₁, and Z_{D}=Z_{I}=2Z₁ in panel (c). It should be noted that these values are selected to provide particular examples, and other ratios may be used for designing the superlattice structure in accordance with the disclosed technology.

In FIG. 4, the thick arrows identify the locations where topological protection leads to an increase in transmission (i.e., 100% or near 100% transmission and thus zero or near zero reflected signals). Each band supports 30 resonances corresponding to the number of periods of the finite superlattice these are manifested in FIG. 4 as narrow sinusoidal functions with envelopes analogous to the band structures in FIG. 3. The lower envelope of the transmission coefficient of the topologically non-conventional bands (2nd and 4th) are asymmetric while the first and third bands, which have conventional topologies, exhibit a standard more symmetrical behavior. We note in panel (a) that the lower envelope of the transmission coefficient of the second band is equal to one at

$$\frac{ω}{{c}_{1}} {d}_{1} = 2.618$$

(what is, k₂d₂=1.2×2.618=π which corresponds to the condition sin k₂d₂=0). The amplitude of the backward propagating wave is zero under this condition. The same condition is satisfied for the fourth band

$$\frac{ω}{{c}_{1}} {d}_{1} = 5.236$$

where k₂d₂=2π.

As evident from panel (a), the transmission coefficient at two regions of the spectrum (thick arrow) provides 100% or nearly 100% transmission of the forward propagating wave, indicating the absence of backward propagating waves. As evident from the units of the horizontal axis in FIG. 4, the locations of the pass bands depend on superlattice characteristics, e.g., transverse speed of sound, c₁ (physical parameter of the superlattice), and the thickness of layer 1, d₁ (a geometrical characteristic of the superlattice). Additional parameters for tuning the pass bands (described in previous equations) include layer 2 characteristics, the number of layers, the material properties of the layers, and the like. In some embodiments, a superlattice with five or more unit cells is utilized. For example, a superlattice with 10 unit cells can be used in one configuration. As noted earlier, in performing the prior analysis, the relationships for the physical parameters of the superlattice were:

$$\frac{{d}_{2}}{{c}_{2}} = 1.2 \frac{{d}_{1}}{{c}_{1}} and F = \frac{{k}_{1} {ρ}_{1} {c}_{1}^{2}}{{k}_{2} {ρ}_{2} {c}_{2}^{2}} = 2 ,$$

where ρ₁, ρ₂ and c₁, c₂ are the density and transverse speed of sound in the two types of materials, respectively,

$${k}_{1} = \frac{ω}{{c}_{1}} and$$

$${k}_{2} = \frac{ω}{{c}_{2}} .$$

In other embodiments, different ratios and F values can be used, and appropriate acoustic material can be selected to achieve the desired density and speed of sound.

The plots in panels (b) and (c) of FIG. 4 illustrate that by modifying the relative characteristic impedances of the two layers, the spectral widths of the pass band regions (with 100% transmission) can be reduced or eliminated. In particular, when the input and detection layers possess higher impedances than layer 1 (panels (b) and (c)), the frequency at which topological protection occurs shifts toward the top of the second and fourth bands. Protection is not total as the lower part of envelope of the transmission coefficient is less than one. Nonetheless, the transmission coefficient in the regions identified by thick arrows may have a high enough value that is suitable for some applications.

Referring back to FIG. 4, the lower part of the envelope of the transmission coefficient for the second band reaches a maximum of 1 in the case of the plot in panel (a), ~0.97 in the case of panel (b) and ~0.91 in panel (c). However, considering conventional waves in the third band, the lower envelop of the transmission reaches a maximum of ~0.71 in case panel (a), ~0.42 in case of panel (b) and ~0.26 in case panel (c). In terms of transmission coefficient, the return loss, RL, can be defined as:

RL=−20 log|T| (7)

We obtain RL=0, 0.26, and 0.82 dB for the topologically protected wave in the second band as a function of the increasing impedance mismatch of panels (a), (b) and (c). For the optimum wave in the third band, we obtain: RL=2.97, 7.53, and 11.70 dB, respectively, for configurations corresponding to panels (a), (b) and (c). From a technological point of view, the last two cases exceed the recommended industry threshold value of 6 dB. The performance of the topologically protected wave in the fourth band is less than that of the second band but still significantly better than the performance of the conventional bands.

To facilitate understanding of the disclosed embodiments, we have discussed the performance of topologically protected bulk elastic waves in finite superlattices in terms of reduction of return loss. It is possible to consider a thin film cut out of the superlattice along a direction parallel to the x direction (e.g., film with surfaces perpendicular to the superlattice layers). For a suspended thin film superlattice, we must consider boundary conditions of stress-free surfaces. This type of condition simply multiplies the displacement given by Eqs. (2a,b) by a function representing the standing wave character of the wave in the direction of the film thickness. This solution does not affect the topological property of the waves along x. In the case of a thin film supported by a rigid substrate (approximating the configuration of a Love wave device), a free-stress boundary condition can be applied to on one side of the film and zero-displacement condition on the other side. These conditions only affect the displacement field characteristics in the direction perpendicular to the film and again do not affect the topology of the wave along the x direction.

As illustrated herein, acoustic material comprising superlattices can be construed to allow propagation of acoustic waves with non-zero amplitude in the forward direction but have zero (or nearly zero) amplitudes when propagating in the opposite direction. These one-way propagating, topologically protected, waves are associated with elastic bands with non-zero Berry phase and their existence does not require breaking time-reversal symmetry. In one example configuration, we evaluated the transmission of the topologically protected waves through a prototypical acoustic wave device with a finite size superlattice sandwiched between an input and a detection layer with different impedances than those of the superlattice constitutive materials. Topologically protected waves lead to a significant benefit for reducing the return loss of the device compared to elastic waves with conventional topology. Notably, the disclosed embodiments differ from the previous solutions that are based on spatio-temporal modulations of acoustic waves using transducers and the like that do not provide the desired loss reduction and require consumption of additional power effectuate the spatio-temporal modulation. The disclosed technology also differs from the orthogonal mode techniques.

The disclosed technology can be implemented in various embodiments to offer practical low-cost and industry compatible solutions for designing next-generation acoustic devices with improved loss characteristics that can be used for telecommunication, sensing and other applications. In some embodiments, superlattices or (equivalently gratings) are constructed with special characteristics that exploit specific acoustic wave mode that corresponds to a zero (or nearly zero) amplitude for the return wave, and non-zero (100% and nearly 100% transmission) in the forward direction. The pass-band frequency can be tuned based on characteristics of the superlattice, such as dimensions and geometries, the choice of materials (elastic coefficients, density, etc.). Increasing the number of units (alternating layers), results in having a smoother transmission coefficient plot, with modulated sinusoidal functions that are closer together.

The disclosed acoustic material can be implemented as part of a bulk acoustic device with alternating layers with differing materials. In some embodiments, the acoustic material may be formed as a thin film that is, for example, cut from the superlattice along a direction parallel to the x direction (e.g., film with surfaces perpendicular to the superlattice layers). For example, the thin film may be positioned on top of a substrate. Various implementations allow the use of the disclosed technology in different types of acoustic devices, and can support both bulk waves and surface waves.

In specific examples described herein, we have demonstrated that static superlattices which do not break time-reversal symmetry can support robust topologically protected elastic waves with non-zero amplitude in the forward propagating direction but zero amplitude in the opposite direction. Compared to conventional elastic waves, topologically protected waves provide a significant benefit for reducing the return loss of the prototypical device. Superlattices supporting topologically protected acoustic waves provide attractive and disruptive solutions for designing the next generation of low-loss acoustic wave devices for telecommunication, sensing and other applications.

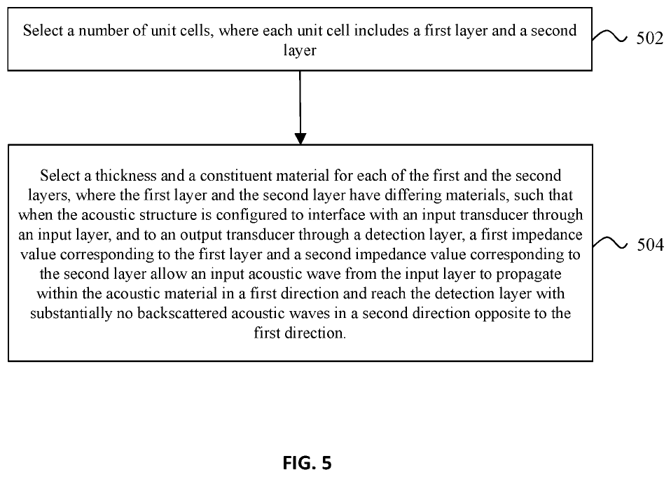

FIG. 5 illustrates a set of operations that can be carried out to produce an acoustical structure with enhanced transmission characteristics in accordance with an example embodiment. At 502, the number of unit cells are selected, where each unit cell includes a first layer and a second layer. At 504, the thickness and the constituent material for each of the first and the second layers are elected. The first layer and the second layer have differing materials, such that when the acoustic structure is configured to interface with an input transducer through an input layer, and to an output transducer through a detection layer, a first impedance value corresponding to the first layer and a second impedance value corresponding to the second layer allow an input acoustic wave from the input layer to propagate within the acoustic material in a first direction and reach the detection layer with substantially no backscattered acoustic waves in a second direction opposite to the first direction.

One aspect of the disclosed embodiments relates to an acoustic wave device that includes an input transducer configured to produce an input acoustic wave, an acoustic material coupled to the input transducer to receive the acoustic wave, and an output transducer coupled to the acoustic material and configured to receive a transmitted acoustic wave from the acoustic material and to produce electrical signals in response to receiving the transmitted acoustic wave. The acoustic material is structured to include a plurality of unit cells, where each unit cell includes a first layer and a second layer, the first layer and the second layer have differing materials, the input transducer is configured to couple the input acoustic wave to the acoustic material through an input layer, the output transducer is configured to receive the transmitted acoustic wave through a detection layer, and impedance values associated with (a) one or both of the input layer or the detection layer, and (b) one or both of the first or the second layers of the unit cells, are selected to allow the input acoustic wave to propagate within the acoustic material in a first direction with substantially no backscattered acoustic waves in a second direction opposite to the first direction.

In one example embodiment, the impedance values are selected to eliminate the backscattered acoustic waves in one or more predetermined range of acoustic frequencies. In another example embodiment, the impedance values are selected to produce a loss through the acoustic material that is less than 6 dBs. In yet another example embodiment, the acoustic material is structured as a finite superlattice and each unit cell has the same thickness as all other unit cells in the superlattice structure. In still another example embodiment, the impedance value of the first layer is selected to be equal to each of the impedance values of the input layer and the detection layer.

According to another example embodiment, the impedance values of each of the input layer and the detection layer is selected to be in a range spanning 1.0 to 2.0 times the impedance value of the first layer. In another example embodiment, the impedance values associated with (a) one or both of the input layer or the detection layer, and (b) one or both of the first or the second layers of the unit cells, are determined in accordance with a geometrical characteristic of the acoustic material or a material characteristic of the acoustic material. In one example embodiment, the acoustic material is structured as a finite superlattice that supports propagation of topologically protected waves, the geometrical characteristic includes one or both of thicknesses of the first layer or the second layer, and the material characteristic includes one or more of: (a) a density of the acoustic material within the first or the second layer, or (b) constituent materials of the first layer or the second layer, causing differing speeds of acoustic waves in the first layer and the second layer.

In another example embodiment, the acoustic material is configured to allow propagation of the input acoustic wave with substantially no backscattered acoustic waves in one or more frequency bands representing one or more pass bands that are each narrower than a full bandwidth of the input acoustic wave. In one example embodiment, the one or more pass bands are configurable based on a geometric or a material property of the superlattice. In still another example embodiment, the acoustic material is structured as a finite superlattice that supports propagation of topologically protected waves with at least 10 unit cells. In yet another example embodiment, the acoustic wave device is incorporated as part of a telecommunication device or a sensor device. In one example embodiment, the acoustic wave device is an acoustic filter.

Another aspect of the disclosed embodiments relates to an acoustic structure for use in an acoustic wave device. The acoustic structure includes a plurality of unit cells, where each unit cell includes a first layer and a second layer, and the first layer and the second layer have differing acoustic materials. The acoustic structure is configured to interface with an input transducer through an input layer, and to an output transducer through a detection layer, where a thickness of the first layer, a thickness of the second layer, a material of the first layer and a material of the second layer are selected to allow an input acoustic wave from the input layer to propagate within the acoustic structure in a first direction and reach the detection layer with substantially no backscattered acoustic waves in a second direction opposite to the first direction.

In one example embodiment, the acoustic structure is configured to eliminate the backscattered acoustic waves in a predetermined one or more ranges of acoustic frequencies. In another example embodiment, the acoustic structure is configured to produce a loss through the acoustic material that is less than 6 dBs in one or more ranges of acoustic frequencies. In yet another example embodiment, the acoustic structure is a finite superlattice to allow propagation of bulk acoustic waves. In still another example embodiment, the acoustic structure is thin film to allow propagation of surface acoustic waves. In one example embodiment, the one or more ranges of acoustic frequencies, or the loss through the acoustic material, is tunable based on: geometrical characteristics that include one or both of the thicknesses of the first layer or the second layer, and material characteristics that include one or more of: (a) a density of the acoustic material within the first or second layer, or (b) constituent materials of the first layer or the second layer, causing differing speeds of acoustic waves in the first layer or the second layers.

Various operations disclosed herein can be implemented using a processor/controller is configured to include, or be coupled to, a memory that stores processor executable code that causes the processor/controller carry out various computations and processing of information. The processor/controller can further generate and transmit/receive suitable information to/from the various system components, as well as suitable input/output (IO) capabilities (e.g., wired or wireless) to transmit and receive commands and/or data. The processor/controller may, for example, provide signals to control the operation of various components such transducer disclosed herein, or to perform various method steps and computations that are disclosed in this patent document.

Various information and data processing operations described herein may be implemented in one embodiment by a computer program product, embodied in a computer-readable medium, including computer-executable instructions, such as program code, executed by computers in networked environments. A computer-readable medium may include removable and non-removable storage devices including, but not limited to, Read Only Memory (ROM), Random Access Memory (RAM), compact discs (CDs), digital versatile discs (DVD), etc. Therefore, the computer-readable media that is described in the present application comprises non-transitory storage media. Generally, program modules may include routines, programs, objects, components, data structures, etc. that perform particular tasks or implement particular abstract data types. Computer-executable instructions, associated data structures, and program modules represent examples of program code for executing steps of the methods disclosed herein. The particular sequence of such executable instructions or associated data structures represents examples of corresponding acts for implementing the functions described in such steps or processes.

Only a few implementations and examples are described and other implementations, enhancements and variations can be made based on what is described and illustrated in this patent document.

1. An acoustic wave device, comprising:
an input transducer configured to produce an input acoustic wave;
an acoustic material coupled to the input transducer to receive the acoustic wave; and
an output transducer coupled to the acoustic material and configured to receive a transmitted acoustic wave from the acoustic material and to produce electrical signals in response to receiving the transmitted acoustic wave, wherein:
the acoustic material is structured to include a plurality of unit cells, each unit cell comprising a first layer and a second layer, the first layer and the second layer having differing materials,
the input transducer is configured to couple the input acoustic wave to the acoustic material through an input layer,
the output transducer is configured to receive the transmitted acoustic wave through a detection layer, and
impedance values associated with (a) one or both of the input layer or the detection layer, and (b) one or both of the first or the second layers of the unit cells, are selected to allow the input acoustic wave to propagate within the acoustic material in a first direction with substantially no backscattered acoustic waves in a second direction opposite to the first direction.

2. The acoustic wave device of claim 1, wherein the impedance values are selected to eliminate the backscattered acoustic waves in one or more predetermined range of acoustic frequencies.

3. The acoustic wave device of claim 1, wherein the impedance values are selected to produce a loss through the acoustic material that is less than 6 dBs.

4. The acoustic wave device of claim 1, wherein the acoustic material is structured as a finite superlattice and wherein each unit cell has the same thickness as all other unit cells in the superlattice structure.

5. The acoustic wave device of claim 1, wherein the impedance value of the first layer is selected to be equal to each of the impedance values of the input layer and the detection layer.

6. The acoustic wave device of claim 1, wherein the impedance values of each of the input layer and the detection layer is selected to be in a range spanning 1.0 to 2.0 times the impedance value of the first layer.

7. The acoustic wave device of claim 1, wherein the impedance values associated with (a) one or both of the input layer or the detection layer, and (b) one or both of the first or the second layers of the unit cells, are determined in accordance with a geometrical characteristic of the acoustic material or a material characteristic of the acoustic material.

8. The acoustic wave device of claim 8, wherein the acoustic material is structured as a finite superlattice that supports propagation of topologically protected waves,
the geometrical characteristic includes one or both of thicknesses of the first layer or the second layer, and
the material characteristic includes one or more of: (a) a density of the acoustic material within the first or the second layer, or (b) constituent materials of the first layer or the second layer, causing differing speeds of acoustic waves in the first layer and the second layer.

9. The acoustic wave device of claim 1, wherein the acoustic material is configured to allow propagation of the input acoustic wave with substantially no backscattered acoustic waves in one or more frequency bands representing one or more pass bands that are each narrower than a full bandwidth of the input acoustic wave.

10. The acoustic wave device of claim 9, wherein the one or more pass bands are configurable based on a geometric or a material property of the superlattice.

11. The acoustic wave device of claim 1, wherein the acoustic material is structured as a finite superlattice that supports propagation of topologically protected waves with at least 10 unit cells.

12. The acoustic wave device of claim 1, wherein the acoustic wave device is incorporated as part of a telecommunication device or a sensor device.

13. The acoustic wave device of claim 1, wherein the acoustic wave device is an acoustic filter.

14. An acoustic structure for use in an acoustic wave device, comprising:
a plurality of unit cells, each unit cell comprising a first layer and a second layer, the first layer and the second layer having differing acoustic materials,
the acoustic structure configured to interface with an input transducer through an input layer, and to an output transducer through a detection layer, wherein
a thickness of the first layer, a thickness of the second layer, a material of the first layer and a material of the second layer are selected to allow an input acoustic wave from the input layer to propagate within the acoustic structure in a first direction and reach the detection layer with substantially no backscattered acoustic waves in a second direction opposite to the first direction.

15. The acoustic structure of claim 14, configured to eliminate the backscattered acoustic waves in a predetermined one or more ranges of acoustic frequencies.

16. The acoustic structure of claim 14, configured to produce a loss through the acoustic material that is less than 6 dBs in one or more ranges of acoustic frequencies.

17. The acoustic structure of claim 14, wherein the acoustic structure is a finite superlattice to allow propagation of bulk acoustic waves.

18. The acoustic structure of claim 14, wherein the acoustic structure is thin film to allow propagation of surface acoustic waves.

19. The acoustic structure of claim 15, wherein the one or more ranges of acoustic frequencies, or the loss through the acoustic material, is tunable based on:
geometrical characteristics that include one or both of the thicknesses of the first layer or the second layer, and
material characteristics that include one or more of: (a) a density of the acoustic material within the first or second layer, or (b) constituent materials of the first layer or the second layer, causing differing speeds of acoustic waves in the first layer or the second layers.

20. A method for producing an acoustical structure with enhanced transmission characteristics, comprising:
selecting a number of unit cells, each unit cell comprising a first layer and a second layer; and
selecting a thickness and a constituent material for each of the first and the second layers, the first layer and the second layer having differing materials, such that when the acoustic structure is configured to interface with an input transducer through an input layer, and to an output transducer through a detection layer, a first impedance value corresponding to the first layer and a second impedance value corresponding to the second layer allow an input acoustic wave from the input layer to propagate within the acoustic material in a first direction and reach the detection layer with substantially no backscattered acoustic waves in a second direction opposite to the first direction.
